(19) United States
(12) Patent Application Publication
(10) Pub. No.: US 2025/0169220 A1
(43) Pub. Date: May 22, 2025

(54) FERROELECTRIC MODULATION OF QUANTUM EMITTERS

(71) Applicant: The Government of the United States of America, as represented by the Secretary of the Navy, Arlington, VA (US)

(72) Inventors: Berend T. Jonker, Davidsonville, MD (US); Sungjoon Lee, McLean, VA (US); Hsun-Jen Chuang, Alexandria, VA (US)

(21) Appl. No.: 18/951,160

(22) Filed: Nov. 18, 2024

Related U.S. Application Data
(60) Provisional application No. 63/602,139, filed on Nov. 22, 2023.

(51) Int. Cl. H01L 31/0264; H01L 31/109; H01L 31/18

(52) U.S. Cl. CPC H10F 77/12; H10F 30/222; H10F 71/138

(57) ABSTRACT

A single photon emitter having a ferroelectric film on a substrate, a monolayer or thin film formed on the ferroelectric where the monolayer or thin film contains a single photon emitter, a conductive contact layer formed over a portion of the monolayer or thin film, and an electrical contact adapted to selectively apply a bias voltage to the conductive layer. The ferroelectric film may comprise poly (vinylidene fluoride-co-trifluoroethylene). The monolayer or thin film formed on the ferroelectric may comprise WS₂. Also disclosed is the related method of forming a single photon emitter.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; nrltechtran@us.navy.mil, referencing Navy Case #211878-US2.

### CROSS-REFERENCE

This application is a nonprovisional application and claims the benefit of U.S. Provisional Application Ser. No. 63/602,139, filed Nov. 22, 2023, entitled “FERROELECTRIC MODULATION OF QUANTUM EMITTERS IN MONOLAYER WS₂” by Berend T. Jonker et al. This provisional application and all references cited herein are hereby incorporated by reference into the present disclosure in their entirety.

### TECHNICAL FIELD

The present invention relates to quantum emitters, and more specifically to controlling emission parameters of quantum emitters.

### BACKGROUND

Quantum photonics promises significant advances in secure communications, metrology, sensing and information processing/computation. Single photon sources, referred to as single photon emitters (SPE) or quantum emitters (QE), are fundamental to this endeavor. However, the lack of high quality single photon sources remains a significant obstacle. Quantum photonic circuits are expected to offer performance and functionality not possible with classical light (Nilsson et al., Quantum Teleportation Using a Light-Emitting Diode. Nat. Photonics 2013, 7, 311-315 and Shomroni et al., All-Optical Routing of Single Photons by a One-Atom Switch Controlled by a Single Photon. Science 2014, 345, 903-906). These applications impose many requirements on QE candidates, including deterministic creation and placement of the emitter, a high degree of single photon purity ranging from 90-100%, and a mechanism to control or modulate such emission.

Two dimensional (2D) materials provide solid state platforms for a wide spectrum of new phenomena with many avenues for technological applications (Lin et al., Recent Advances in 2D Material Theory, Synthesis, Properties, and Applications. ACS Nano 2023, 17, 9694-9747), including quantum information (Liu et al., 2D Materials for Quantum Information Science. Nat. Rev. Mater. 2019, 4, 669-684 and Alfieri et al., Nanomaterials for Quantum Information Science and Engineering, Adv. Mater. 2023, 35, 2109621). These materials also serve as hosts for quantum emitters (Perebeinos, Two Dimensions and One Photon, Nat. Nanotechnol. 2015, 10, 485-486), which are essential building blocks for the photonic processes and circuits envisioned to enable quantum information processing and sensing (Liu et al., 2D Materials for Quantum Information Science. Nat. Rev. Mater. 2019, 4, 669-684 and Alfieri et al., Nanomaterials for Quantum Information Science and Engineering, Adv. Mater. 2023, 35, 2109621). Significant progress has been reported in deterministic creation and placement of QEs in 2D materials using local strain fields in monolayer transition metal dichalcogenides (TMDs), including strain induced by holes in the substrate (Kumar et al., Strain-Induced Spatial and Spectral Isolation of Quantum Emitters in Mono-and Bilayer WSe₂. Nano Lett. 2015, 15, 7567-7573), nanopillars (Li et al., Optoelectronic Crystal of Artificial Atoms in Strain-Textured Molybdenum Disulphide. Nat. Commun. 2015, 6, 7381; Palacios-Berraquero et al., Large-Scale Quantum-Emitter Arrays in Atomically Thin Semiconductors. Nat. Commun. 2017, 8, 15093; Wu et al., Locally Defined Quantum Emission from Epitaxial Few-Layer Tungsten Diselenide. Appl. Phys. Lett. 2019, 114, 213102; and Zhao et al., Site-Controlled Telecom-Wavelength Single-Photon Emitters in Atomically-Thin MoTe₂. Nat. Commun. 2021, 12, 6753), nanoindentation techniques (Rosenberger et al., Quantum Calligraphy: Writing Single-Photon Emitters in a Two-Dimensional Materials Platform. ACS Nano 2019, 13,904-912 and So et al., Electrically Driven Strain-Induced Deterministic Single-Photon Emitters in a van Der Waals Heterostructure. Sci. Adv. 2021, 7, 3176), and nanoparticles (Kim et al., High-Density, Localized Quantum Emitters in Strained 2D Semiconductors. ACS Nano 2022, 16, 9651-9659). Although relatively high single photon emission purity has been reported for select samples (Kumar et al., Resonant Laser Spectroscopy of Localized Excitons in Monolayer WSe₂, Optica 2016, 3, 882-886), in many cases the purity is severely compromised by the emission of semi-classical light arising from a variety of material-dependent sources commonly associated with defect bound excitons which is spectrally degenerate with the quantum light and cannot be simply filtered out.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The purpose of the invention is to control the emission purity, intensity, wavelength and other emission parameters of single photon emitters by the ferroelectric polarization of an adjacent ferroelectric layer. A specific example is to control the single photon emission purity of quantum emitters in a monolayer film of the transition metal dichalcogenide material tungsten disulphide (WS₂) by switching the polarization of a ferroelectric material upon which the WS₂ monolayer is placed. The single photon emission purity is high for one orientation of the ferroelectric polarization (e.g. “up”), so that it produces quantum light, and is low when the orientation of the ferroelectric polarization is reversed (e.g. “down”), so that the emitter now produces semi-classical light.

This approach enables nonvolatile modulation of the emission character by reversing the polarization of the ferroelectric domain under a given emitter, thereby switching between the quantum and semi-classical regimes. We are aware of no other mechanism to accomplish this.

This modulation may offer an additional tool for secure communications and quantum encryption schemes based upon single photon sources. This provides another avenue for encoding quantum photonic information, complementing more complex approaches such as spectral shearing (Wright et al., Spectral Shearing of Quantum Light Pulses by Electro-Optic Phase Modulation. Phys. Rev. Lett. 2017, 118, 023601).

The planar atomic layered character of 2D materials offers many advantages over the more well studied QE candidates such as InAs-based quantum dots or nitrogen vacancy centers in diamond (Liu et al., 2D Materials for Quantum Information Science. Nat. Rev. Mater. 2019, 4, 669-684 and Alfieri et al., Nanomaterials for Quantum Information Science and Engineering. Adv. Mater. 2023, 35, 2109621). They are relatively easy to synthesize and lack the out-of-plane bonding typical of other materials, so that they can be readily integrated with a variety of substrates without the complications of lattice matching. In addition, the QE site is located very near the surface, thus avoiding losses from total internal reflection and providing high photon extraction efficiency. Surface proximity also makes these QEs attractive for heterogeneous integration with different materials or architectures, for instance via evanescent coupling to waveguides in photonic integrated circuits (PICs).

This approach should also work for other QE layers and other ferroelectrics. Examples of other QE layers include other transition metal dichalcogenides, such as WSe₂ and MoTe₂, and other ferroelectrics include materials such as lead zirconium titanate (PZT), aluminum scandium nitride, hafnium oxide, and barium titanate, etc.

### BRIEF DESCRIPTION OF THE DRAWINGS

FIGS. 1A and 1B depict a WS₂ single photon emitter on a ferroelectric P(VDF-TrFE)/Si substrate. FIG. 1A shows how using the nanoindentation technique with an AFM tip, quantum emitters are created by the high local strain fields at specific indented positions on monolayer WS₂. FIG. 1B shows how applying bias with a conductive PFM tip situated on graphite, the ferroelectric P(VDF-TrFE) beneath the monolayer WS₂ becomes polarized, with some component of the polarization aligned along the surface normal and pointing either in or out of the surface, depending upon the tip bias.

FIG. 2 depicts the localization of WS₂ single photon emitters using AFM indentation. The inset is a fluorescence image showing that spatial positions of emission features correlate with positions of nanoindents. Scale bar, 5 μm. Photoluminescence spectra obtained from the monolayer WS₂ away from an indent (dashed curve, dashed circle on image) are broad and featureless, while those obtained on an indent (solid curve, solid circle on image) show sharp peaks characteristic of SPEs, further confirming that SPEs are created at the nanoindent sites. The data were acquired at 5 K with 532 nm CW laser excitation and power density of 0.4 μW/μm².

FIGS. 3A-F depict optical characteristics of a ferroelectrically modulated WS₂ single photon emitter. FIG. 3A shows the photoluminescence (PL) spectrum of an indented WS₂ emitter on the up-domain P(VDF-TrFE). FIG. 3B shows the corresponding g⁽²⁾(t) plot with g⁽²⁾(t=0) value of 0.19±0.03, demonstrating that it is a high purity single photon emitter. The emitter lifetime obtained from these data is 45.0±2.2 ns. FIG. 3C shows the PL spectrum of the same emitter after switching the orientation of the underlying P(VDF-TrFE) to the down-domain orientation. Note the appearance of a new feature at 600-602 nm. FIG. 3D shows the corresponding g⁽²⁾(t) plot with g⁽²⁾(t=0) value of 0.55±0.07, indicating that the emission is now classical in character. The emitter lifetime obtained from these data is 45.0'4.0 ns. FIG. 3E shows the PL spectrum of the same emitter after the polarization of the underlying P(VDF-TrFE) has been switched back to the up-domain orientation. FIG. 3F shows the corresponding g⁽²⁾(t) plot with g⁽²⁾(t=0) value of 0.18±0.02, demonstrating that the emitter returns to its original state as a high purity single photon emitter. The emitter lifetime obtained from these data is 12.0±0.5 ns. The highlighted vertical bars in the PL spectra represent the effective 5 nm filter bandwidth used for g⁽²⁾(t) measurements. Black dots represent the data points, solid lines show the fitting results, and dashed lines indicate g⁽²⁾(t)=0.5, the threshold value confirming a single photon emitter. All the data were acquired at 16 K with a 532 nm laser and 70 nW of power measured at the sample. Small variations in emitter wavelength and lifetime are attributed to slight changes in the local strain field due to thermal cycling required to change the ferroelectric polarization.

FIG. 4 depicts a summary of g²(t=0) values for multiple emitters as a function of the orientation of the ferroelectric domain. Localized emitters in the monolayer WS₂ over “up-domains” in the ferroelectric film emit high purity quantum light with g²(0)<0.5, while those over “down-domains” emit semi-classical light with g²(0)>0.5.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present invention involves the nonvolatile and reversible control of single photon emission purity by integrating an SPE layer with a ferroelectric film. To illustrate, we use an example system consisting of monolayer tungsten disulfide (WS₂) film on an organic ferroelectric polymer film, poly(vinylidene fluoride-co-trifluoroethylene) (P(VDF-TrFE)). This approach should also work for other QE layers and other ferroelectrics. We create an emitter in the WS₂, and are able to toggle the emission between high purity quantum light (characterized by sub-Poissonian statistics) and semi-classical light (characterized by Poissonian statistics) by switching the ferroelectric polarization of the P(VDF-TrFE) with a bias voltage. We further demonstrate that the monolayer WS₂ operates as a transparent top gate—application of a bias voltage to the WS₂ switches the ferroelectric polarization of the underlying P(VDF-TrFE) film.

Specifically, we show that light emission from SPEs in WS₂ can be toggled between quantum and classical regimes by reversal of the ferroelectric polarization in an adjacent layer, providing nonvolatile control of single photon emission. Localized emitters in the monolayer WS₂ over “up-domains” in the ferroelectric film emit high purity quantum light, while those over “down-domains” emit semi-classical light.

We achieve single photon emission purity P as high as 94%, as determined by the measured second order correlation function g⁽²⁾(t−0) value of 0.06, where P=1−g⁽²⁾(0), the highest purity reported for WS₂ SPEs to our knowledge. (Palacios-Berraquero et al., Atomically Thin Quantum Light-Emitting Diodes, Nat. Commun. 2016, 7, 12978 and Cianci et al., Spatially Controlled Single Photon Emitters in hBN-Capped WS₂ Domes, Adv. Opt. Mater. 2023, 11, 2202953). This heterostructure introduces a new paradigm for control of quantum emitters by combining the nonvolatile ferroic properties of a ferroelectric with the radiative properties of the zero-dimensional atomic scale emitters embedded in the two-dimensional WS₂ semiconductor monolayer.

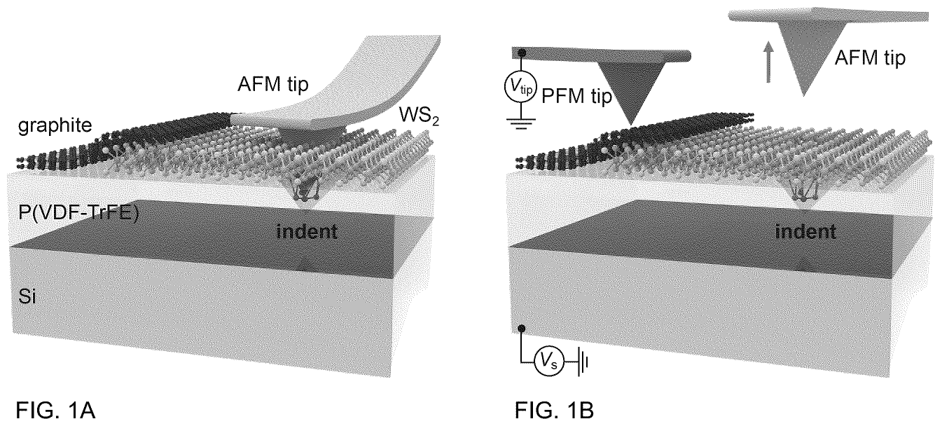

The samples consist of monolayer films of WS₂ grown by chemical vapor deposition (CVD) and mechanically transferred onto a 260 nm film of P(VDF-TrFE), which had been previously transferred onto a highly doped (p++) Si substrate. We deterministically create and place quantum emitters within the WS₂ using the atomic force microscope (AFM) nanoindentation technique described previously and illustrated in FIG. 1A, where the P(VDF-TrFE) serves as a deformable polymer (Rosenberger et al., Quantum Calligraphy: Writing Single-Photon Emitters in a Two-Dimensional Materials Platform, ACS Nano 2019, 13, 904-912). When the AFM tip is removed, the WS₂ conforms to the contour of the nanoindent, and the local strain field activates single photon emission from atomic scale defect states in the WS₂. For the top electrical contact, graphite was then transferred and partially covered the WS₂, and a conductive piezo force microscopy (PFM) tip was used to apply a bias voltage to switch the polarization of the P(VDF-TrFE) beneath the WS₂, as shown in FIG. 1B.

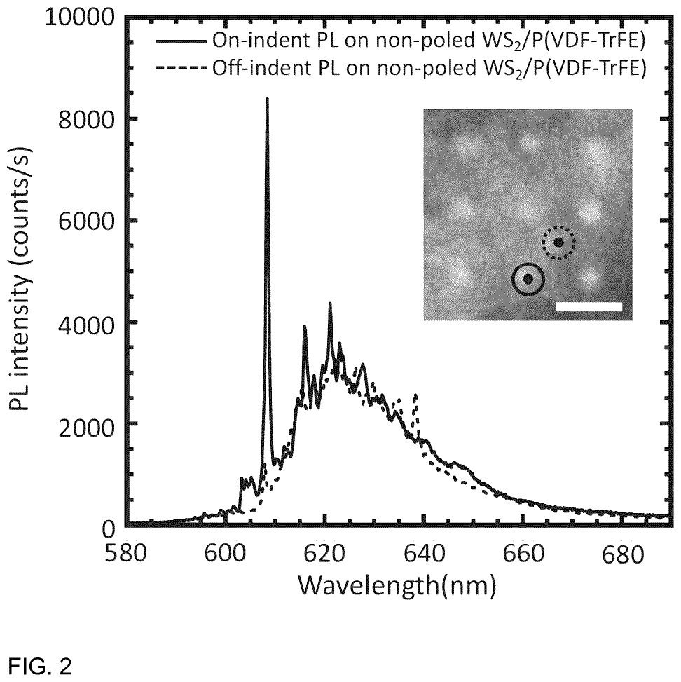

A proximal probe-based nano-indentation method (Rosenberger et al., Quantum Calligraphy: Writing Single-Photon Emitters in a Two-Dimensional Materials Platform. ACS Nano 2019, 13, 904-912) was employed to achieve deterministic creation and precise positioning of quantum emitters in monolayer WS₂ on the P(VDF-TrFE)/Si substrate. Controlled indents were made at specific locations using an AFM tip (FIG. 1A), causing deformation in the WS₂/P(VDF-TrFE) heterostructure and generating a highly localized strain field which activates single photon emitters in the WS₂. The spatial fluorescence image of the sample (inset of FIG. 2) shows bright points of emission coinciding with most of the nanoindents in the heterostructure. As shown in FIG. 2, photoluminescence spectra obtained at low temperature (T=5 K) from such an indent exhibit sharp bright peaks characteristic of SPEs (solid trace), while spectra obtained from non-indented areas of the WS₂ show only broad low intensity background in the same spectral region (dashed trace). All indented sites show sharp bright peaks consistent with SPEs. Because some indents exhibit more than one such emission site, making quantitative analysis of an individual emitter difficult within our spatial resolution, in the following we focus on those sites where one single emitter can be clearly identified and analyzed within the spatial resolution of our instrument.

Subsequent application of either a negative or positive bias voltage via the PFM tip and graphite contact generates either an “up” or “down” polarization domain, respectively, in the P(VDF-TrFE) film under the WS₂ flake containing the indented region and emitter. This ferroelectric domain orientation has a profound effect on the character of the light emitted from a given emitter, and we examine the corresponding photophysics by measuring the second order autocorrelation function, g⁽²⁾(t). A dip in g⁽²⁾(t) at zero time delay is referred to as antibunching, and indicates a reduced probability of detecting more than one photon. Values of g⁽²⁾(t=0)<0.5 indicate that the light originates from a quantum emitter, i.e. a single photon source rather than from a conventional source emitting “semi-classical” light such as typical electro-or photo-luminescence. For an ideal quantum emitter, g⁽²⁾(t=0)=0, i.e. the probability of simultaneously emitting two photons is zero, corresponding to a purity of 100%.

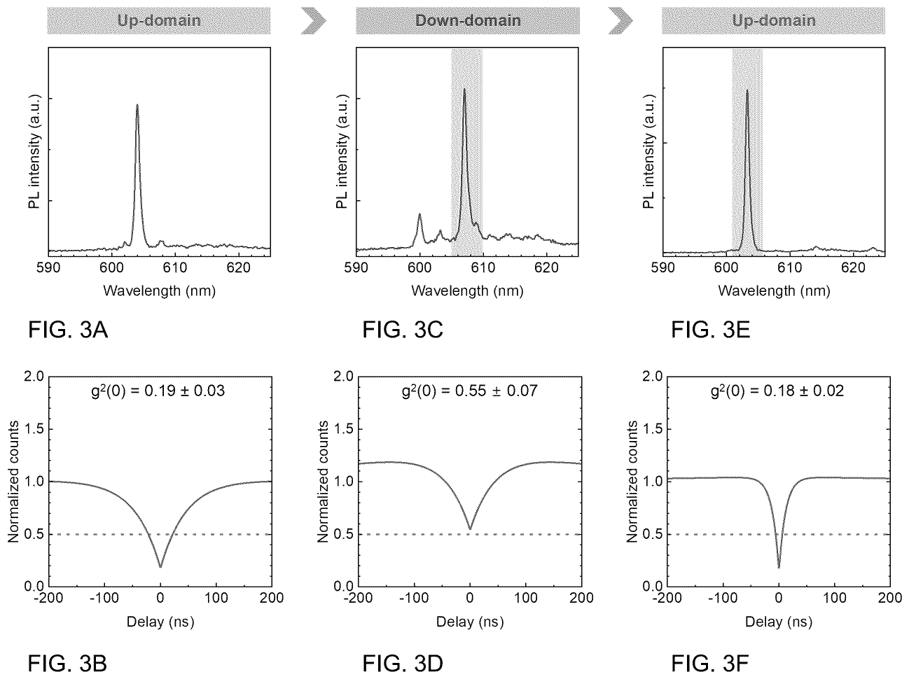

PL spectra and g⁽²⁾(t) data obtained at 16 K are presented in FIGS. 3A-F as the ferroelectric domain polarization is changed from “up” (FIGS. 3A and B) to “down” (FIGS. 3C and D), and back to “up” (FIGS. 3E and F). Each PL spectrum exhibits low background and is dominated by a narrow intense peak at ˜604-607 nm of comparable intensity (within a factor of 3) with a full-width-at-half-maximum (FWHM) of ˜0.6 nm, consistent with a single photon emitter. The Hanbury Brown and Twiss (HBT) methodology was used to acquire g⁽²⁾(t) data from the highlighted region in each spectrum. No background correction was applied to either the PL spectra or g⁽²⁾(t) data.

For the initial “up” domain orientation (FIGS. 3A and B), we obtain a value g⁽²⁾(t=0)=0.19±0.03, confirming that in this configuration, the emitter is a source of high purity quantum light approaching the purity required for applications such as quantum cryptography/random number generation or quantum key distribution (Aharonovich, et al., Solid-State Single-Photon Emitters. Nat. Photonics 2016, 10, 631-641). This is comparable to the value g2(t=0)=0.14±0.05 we obtain for SPEs created in a WS₂ reference sample fabricated with the same nanoindentation procedure, but using a non-ferroelectric polymer, poly(methyl methacrylate) (PMMA), as the deformable substrate. For comparison, values of g⁽²⁾(t=0) for SPEs in hBN-capped WS₂ monolayers reported in the literature ranged from 0.15 to 0.31 (Wright et al., Spectral Shearing of Quantum Light Pulses by Electro-Optic Phase Modulation. Phys. Rev. Lett. 2017, 118, 023601 and Palacios-Berraquero et al., Atomically Thin Quantum Light-Emitting Diodes. Nat. Commun. 2016, 7, 12978).

After reversing the P(VDF-TrFE) polarization to the “down” orientation (FIGS. 3C and D), we observe that an additional feature appears in the PL at a shorter wavelength (˜600-602 nm) than the primary emitter peak (607 nm), indicating the formation of a state at higher energy from which radiative recombination is allowed. This is accompanied by a dramatic change in g⁽²⁾(t), with a much higher value g⁽²⁾(t=0)=0.55±0.07, indicating that the light originating from this emitter is no longer quantum in character, but in fact is now semi-classical light.

After again reversing the P(VDF-TrFE) polarization to return it to the “up” orientation (FIG. 3E and F), the PL peak at shorter wavelength is substantially reduced in intensity, and the measured g⁽²⁾(t=0)=0.18±0.02 for the prominent peak at 604 nm indicates that the emitter is again a source of high purity quantum light. Small variations in emitter wavelength and lifetime are attributed to slight changes in the local strain field due to thermal cycling required to change the ferroelectric polarization.

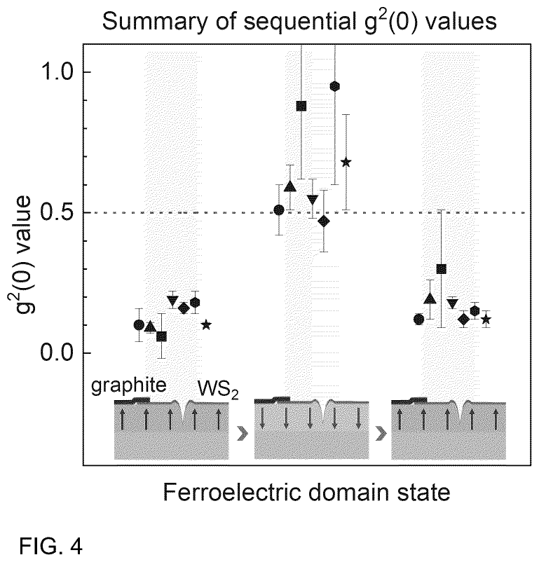

Thus, the orientation of the polarization domain in the P(VDF-TrFE) film determines the character of the light from the emitting state in the adjacent WS₂, enabling one to toggle back and forth from the quantum to semi-classical emission regimes. We observe this sequence of behavior for other emission sites where a single feature can be reliably measured, with single photon purities as high as 94%. A summary of g²(0) values for multiple emitters as a function of the orientation of the ferroelectric domain is shown in FIG. 4, demonstrating the consistency of this behavior.

One might reasonably expect that larger changes in surface charge density, produced by “stronger” ferroelectrics such as AlScN (remnant polarization of ˜70-130 μC/cm²) recently used for ferroelectric field effect transistors (Kim et al., Tuning Polarity in WSe₂/AlScN FeFETs via Contact Engineering. ACS Nano 2024, 18, 4180-4188), would result in more pronounced effects. However, we would also expect these effects to saturate at some given value of the surface charge density induced by the ferroelectric polarization. Our observation that the emitted light toggles between quantum and semi-classical character upon reversing the polarization of a relatively weak ferroelectric like P(VDF-TrFE) (remnant polarization of ˜10-25 μC/cm²) suggests that the saturation threshold is relatively low for the specific combination of strain and polarization realized in the nanoindented WS₂/P (VDF-TrFE) system. It is conceivable that the polarization threshold may be different for a different heterostructure of strained TMD and ferroelectric.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A single photon emitter heterostructure comprising
a ferroelectric material or a ferroelectric film formed on a substrate;
a monolayer or thin film formed on the ferroelectric material or ferroelectric film, wherein the monolayer or thin film contains a single photon emitter;
a conductive contact layer formed over a portion of the monolayer or thin film containing the single photon emitter; and
an electrical contact adapted to selectively apply a bias voltage to the conductive layer.

2. The single photon emitter heterostructure of claim 1, wherein the substrate is silicon.

3. The single photon emitter heterostructure of claim 1, wherein the substrate is a semiconductor or an insulator.

4. The single photon emitter heterostructure of claim 3, wherein the substrate comprises GaAs, InP, GaN, SiC, Al₂O₃, or SiGe.

5. The single photon emitter heterostructure of claim 1, wherein the ferroelectric material or ferroelectric film comprises poly(vinylidene fluoride-co-trifluoroethylene P(VDF-TrFE).

6. The single photon emitter heterostructure of claim 1, wherein the ferroelectric material or ferroelectric film comprises one of the following: doped HfO₂, BaTiO₂, lithium niobate, a formulation of lead zirconium titanate (PZT) or lead magnesium niobate lead titanate (PMN-PT), scandium-doped III-N, or boron-doped III-N.

7. The single photon emitter heterostructure of claim 1, wherein the monolayer or thin film containing the single photon emitter is a semiconductor, is a transition metal dichalcogenide, or comprises hBN.

8. The single photon emitter heterostructure of claim 1, wherein the monolayer or thin film comprises WS₂.

9. The single photon emitter heterostructure of claim 1, wherein the conductive contact layer comprises graphene or graphite.

10. The single photon emitter heterostructure of claim 1, wherein the conductive contact layer comprises a transparent conductive oxide.

11. The single photon emitter heterostructure of claim 1, wherein the conductive contact layer comprises indium tin oxide.

12. The single photon emitter heterostructure of claim 1, wherein the monolayer or thin film containing the single photon emitter is draped over a structure that is pre-formed from the ferroelectric material or ferroelectric film.

13. The single photon emitter heterostructure of claim 12, wherein the structure comprises a pillar or pyramid.

14. A single photon emitter comprising
a poly(vinylidene fluoride-co-trifluoroethylene P(VDF-TrFE) film formed on a substrate, wherein the P(VDF-TrFE) film includes a nanoindentation formed therein;
a tungsten disulfide (WS₂) monolayer formed on a first portion of the P(VDF-TrFE) film, wherein the WS₂ monolayer extends into the nanoindentation;
a graphite layer formed over a portion of the WS₂ monolayer and a second portion of the P(VDF-TrFE) film; and
a conductor adjacent to the graphite layer and adapted to selectively apply a bias voltage to the graphite layer.

15. The single photon emitter of claim 14, wherein the substrate is silicon.

16. A method of forming a single photon emitter comprising
providing a ferroelectric material or forming a ferroelectric film on a substrate;
providing a layer containing a single photon emitter or growing a layer containing a single photon emitter on a first portion of the ferroelectric material or ferroelectric film;
forming a nanoindentation in the ferroelectric material or ferroelectric film, wherein the layer extends into the nanoindentation;
forming a conductive layer over a portion of the layer; and
positioning a conductor adjacent to the conductive layer to selectively apply a bias voltage to the conductive layer.

17. The method of claim 16, wherein the substrate is silicon.

18. The method of claim 16, wherein the substrate is a semiconductor or an insulator.

19. The method of claim 18, wherein the substrate comprises GaAs, InP, GaN, SiC, Al₂O₃, or SiGe.

20. The method of claim 16, wherein the ferroelectric material or ferroelectric film comprises poly(vinylidene fluoride-co-trifluoroethylene P(VDF-TrFE).

21. The method of claim 16, wherein the ferroelectric material or ferroelectric film comprises one of the following: doped HfO₂, BaTiO₂, lithium niobate, a formulation of lead zirconium titanate (PZT) or lead magnesium niobate lead titanate (PMN-PT), scandium-doped III-N, or boron-doped III-N.

22. The method of claim 16, wherein the monolayer or thin film is a semiconductor, is a transition metal dichalcogenide, or comprises hBN.

23. The method of claim 16, wherein the monolayer or thin film comprises WS₂.

24. The method of claim 16, wherein the conductive layer comprises graphene or graphite.

25. The method of claim 16, wherein the conductive contact layer comprises a transparent conductive oxide.

26. The method of claim 16, wherein the conductive contact layer comprises indium tin oxide.

27. A single photon emitter heterostructure comprising
a layer containing a single photon emitter formed on a substrate;
a ferroelectric film formed on the single photon emitter layer;
a conductive contact layer formed on the ferroelectric film; and
an electrical contact adapted to selectively apply a bias voltage to the conductive contact layer.
